(19) United States
(12) Patent Application Publication
(10) Pub. No.: US 2006/0139892 A1
(43) Pub. Date: Jun. 29, 2006

(54) Heat dissipating arrangement for an electronic appliance

(75) Inventor: Cornelis Johannes Mies, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: koninklijke phillips electronics n.v.

(21) Appl. No.: 10/543,398

(22) PCT Filed: Dec. 18, 2003
(86) PCT No.: PCT/IB03/06111

§ 371 Date: Jul. 26, 2005

(30) Foreign Application Priority Data
Jan. 29, 2003 (EP) 031200180.3

(51) Int. Cl. H05K 7/20

(52) U.S. Cl. 361/720

(57) ABSTRACT

An electronic appliance, such as a computer and the like, comprising a printed circuit board with printed circuits arranged thereon and electromagnetic components electrically connected thereto, as well as a heat dissipating arrangement for dissipating heat generated by the components to the surrounding atmosphere, a special feature being the fact that the heat dissipating arrangement comprises a heat sink with several separate thermal conductors which are thermically connected to the printed circuits, which thermal conductors can be arranged on the printed circuit board in various positions, each position corresponding to a predetermined heat dissipation direction.

The invention relates to an electronic appliance, such as a computer and the like, comprising a printed circuit board with printed circuits arranged thereon and electromagnetic components electrically connected thereto, as well as a heat dissipating arrangement for dissipating heat generated by the components to the surrounding atmosphere. It is noted that the invention extends to electronic equipment in the broadest sense of the word, but in particular to computers, such as laptop computers, notebooks, servers etc., as well as lamp drivers and power convertors for lighting applications.

Such an electronic appliance in the form of the computer is known from U.S. Pat. No 6,064,570 (Wang et al). Computers are becoming more and more compact, so that the energy consumption of the computer per unit volume of the housing thereof increases dramatically. As a result, the dissipation of heat generated by components present in the housing of the computer, such as processors, is becoming all the more essential in order to prevent said components from exhibiting failures as the temperature in the housing increases, with all the harmful consequences thereof. The aforesaid U.S. patent specification shows a printed circuit board whose copper strips (called “tracks” in practice) are electrically connected to electromagnetic components, such as processors, memory modules, input/output devices etc. The heat dissipating arrangement that is described therein consists of a fan mounted in a wall of the housing and a so-called “heat sink”, which is attached to a processor. Said heat sink comprises various thermal conductors, and heat generated by the processor is transferred first to the thermal conductors and subsequently to the surrounding air, and the air that has thus been heated is dissipated to the surrounding atmosphere by means of the fan. The shape of the thermal conductors of this known heat sink has been designed to render the heat sink suitable for being positioned on a printed circuit board either perpendicularly to a heat dissipation direction or parallel to a heat dissipation direction, depending on the type of computer that is used.

One drawback of the computer as described in the aforesaid U.S. patent publication is the fact that the heat sink used therein must be mechanically connected to the processor, whilst the heat sink can only be arranged in two orientations on the printed circuit board.

The object of the invention is to obviate the drawbacks of the prior art as indicated above, and in order to accomplish that objective an electronic appliance of the kind referred to in the introduction is characterized in that the heat dissipating arrangement comprises a heat sink with several separate thermal conductors which are thermically (preferably electrically) connected to the printed circuits, which thermal conductors can be arranged on the printed circuit board in various positions, each position corresponding to a predetermined heat dissipation direction. In other words, one advantage obtained by designing the heat sink as separate (single) thermal conductors which are electrically and therefore thermically connected to the printed circuits is the fact that heat generated by, for example, a processor can be transferred thereto via the printed circuits (so that there is no need for a mechanical connection to such a processor), whilst another advantage is the fact that the thermal conductors can be mounted in various positions on the printed circuit board (each position corresponding to a heat dissipating arrangement associated with a particular type of electronic appliance). A single thermal conductor can also be useful for locally cooling a soldering region on the printed circuit board.

In one preferred embodiment of an electronic appliance according to the invention, the thermal conductors can be arranged on the printed circuit board in a position perpendicularly to a predetermined heat dissipation direction or in a position parallel to a predetermined heat dissipation direction. In another preferred variant, the thermal conductors can be arranged on the printed circuit board between a position perpendicularly to a predetermined heat dissipation direction and a position parallel to a predetermined heat dissipation direction. As a result, the present heat sink is a multipurpose heat sink, therefore, in the sense in that it can be used in any computer having any heat dissipating arrangement.

In another preferred embodiment of an electronic appliance according to the invention, the printed circuit board comprises various attachment points for each thermal conductor, each attachment point corresponding to a predetermined heat dissipation direction. More in particular, the thermal conductors are soldered on the printed circuit board, so that said attachment points are soldering points present on the printed circuits or being in electrical contact therewith.

In another preferred embodiment of an electronic appliance according to the invention, the thermal conductors electrically connect the printed circuit board to another printed circuit board.

The invention also relates to a thermal conductor apparently suitable for use in an electronic appliance according to the invention.

The invention furthermore relates to a method of manufacturing an electronic appliance, such as a computer and the like, starting from a printed circuit board comprising printed circuits arranged thereon and electromagnetic components electrically connected thereto, and a heat dissipating arrangement for dissipating heated generated by components to the surrounding atmosphere, characterized in that the heat dissipating arrangement consists of a heat sink comprising several separate thermal conductors which are electrically connected to the printed circuits, which thermal conductors can be arranged-in various positions on the printed circuit board, each position corresponding to a predetermined heat dissipation direction.

The invention will now be explained in more detail with reference to figures illustrated in a drawing, in which:

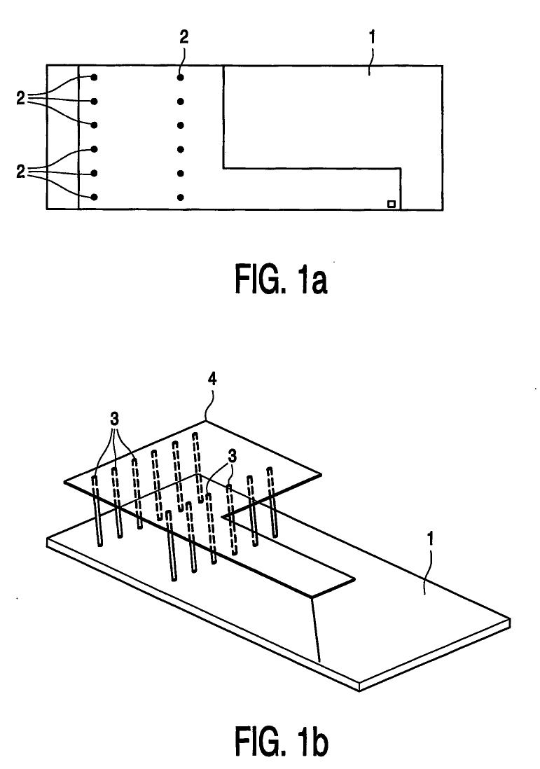

FIGS. 1a-4a are schematic top plan views of a printed circuit board, showing various soldering regions arranged on the printed circuit board in preparation of the attachment thereto of thermal conductors (according to the invention) in different positions; and

FIGS. 1b-4b are schematic, perspective views of the printed circuit board with the thermal conductors of FIGS. 1a-4a soldered thereon, whilst furthermore a second printed circuit board is provided.

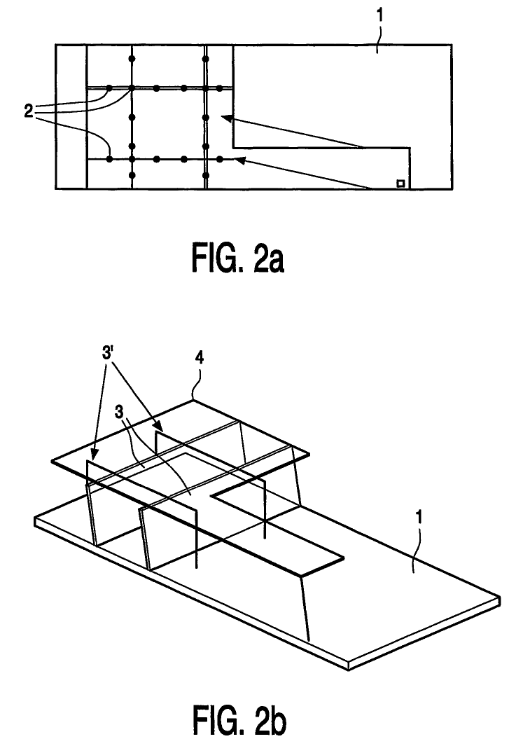

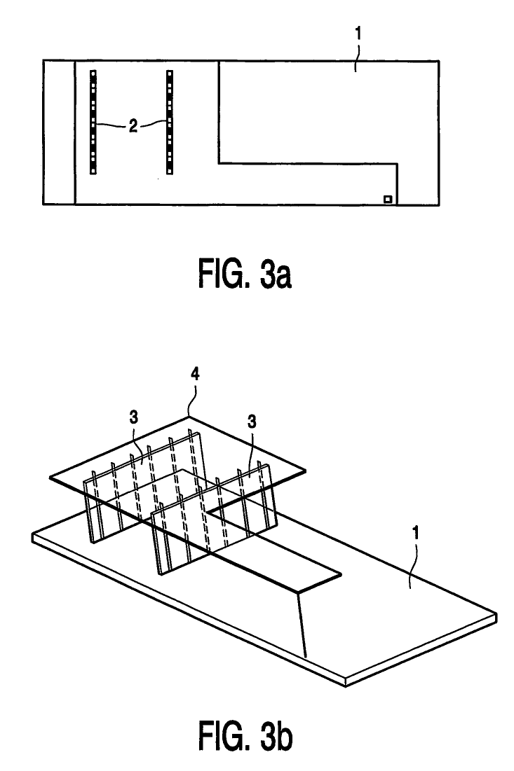

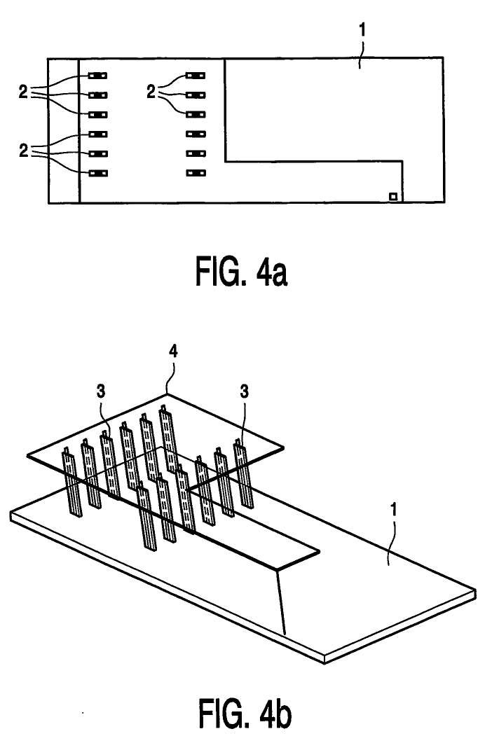

FIGS. 1a-4a show a printed circuit board 1, each figure showing different soldering regions 2 arranged in preparation on the printed circuit board; in all cases, however, the soldering regions 2 are present on the printed circuits (not shown) of the printed circuit board 1, thus enabling an easy and efficient thermal conduction along said circuits. In FIGS. 1a-4a, the soldering regions 2 are, successively, twelve small spots (FIG. 1a), eighteen larger spots (FIG. 2a), two large strips (FIG. 3a) and twelve small strips (FIG. 4a).

FIGS. 1b-4b corresponds to FIGS. 1a-4 4a, respectively, with separate thermal conductors according to the invention, indicated at 3, being soldered on the printed circuit board by means of the prepared soldering regions 2 as shown in FIGS. 1a-4a. Heat generated by, for example, a processor (not shown) present on the printed circuit board 1 is transferred to the thermal conductors 3 via the printed circuits on the printed circuit board 1. Said thermal conductors in turn dissipate the heat to the surrounding air, whilst the fan present in the housing of the printed circuit board, for example, discharges said heat into the atmosphere. The thermal conductors function as heat sinks, therefore, but they also function as electrically conducting connections between the printed circuit board 1 and the second printed circuit board 4 disposed thereabove. The thermal conductors also have a cooling effect on the soldering regions 2 for that matter. FIG. 2b shows the plate-shaped thermal conductors in two possible orientations: the first orientation is indicated at 3 by means of arrows, the second orientation is indicated at 3′, likewise by means of arrows.

It is noted that the invention is not limited to the embodiments as described above, it also extends to other variants falling within the scope of the appended claims.

1. An electronic appliance, such as a computer and the like, comprising a printed circuit board with printed circuits arranged thereon and electromagnetic components electrically connected thereto, as well as a heat dissipating arrangement for dissipating heat generated by the components to the surrounding atmosphere, characterized in that the heat dissipating arrangement comprises a heat sink with several separate thermal conductors which are thermically connected to the printed circuits, which thermal conductors can be arranged on the printed circuit board in various positions, each position corresponding to a predetermined heat dissipation direction.

2. An electronic appliance according to claim 1, wherein the thermal conductors can be arranged on the printed circuit board in a position perpendicularly to a predetermined heat dissipation direction or in a position parallel to a predetermined heat dissipation direction.

3. An electronic appliance according to claim 1, wherein the thermal conductors can be arranged on the printed circuit board between a position perpendicularly to a predetermined heat dissipation direction and a position parallel to a predetermined heat dissipation direction.

4. An electronic appliance according to claim 1, wherein the printed circuit board comprises various attachment points for each thermal conductor, each attachment point corresponding to a predetermined heat dissipation direction.

5. An electronic appliance according to claim 1, wherein the thermal conductors are soldered on the printed circuit board.

6. An electronic appliance according to claim 1, wherein the thermal conductors electrically connect the printed circuit board to another printed circuit board.

7. A thermal conductor apparently suitable for use in an electronic appliance according to claim 1.

8. A method of manufacturing an electronic appliance, such as a computer and the like, starting from a printed circuit board comprising printed circuits arranged thereon and electromagnetic components thermically connected thereto, and a heat dissipating arrangement for dissipating heated generated by components to the surrounding atmosphere, characterized in that the heat dissipating arrangement consists of a heat sink comprising several separate thermal conductors which are electrically connected to the printed circuits, which thermal conductors can be arranged in various positions on the printed circuit board, each position corresponding to a predetermined heat dissipation direction.
